(19) United States
(12) Patent Application Publication
(10) Pub. No.: US 2025/0228005 A1
(43) Pub. Date: Jul. 10, 2025

(54) CHIP ON FILM AND DISPLAY DEVICE INCLUDING THE SAME

(71) Applicant: LG Display Co., Ltd., Seoul (KR)

(72) Inventor: Jong Hyuk LEE, Paju-si (KR)

(21) Appl. No.: 18/960,405

(22) Filed: Nov. 26, 2024

(30) Foreign Application Priority Data
Jan. 8, 2024 (KR) 10-2024-0002815

(51) Int. Cl. H01L 27/12

(52) U.S. Cl. CPC H10D 86/60; H10D 86/443

(57) ABSTRACT

A chip on film includes a driver integrated circuit, an input pad part including a first input pad connected to the driver integrated circuit and a second input pad separated from the driver integrated circuit, and an output pad part including a first output pad connected to the driver integrated circuit, a second output pad directly connected to the second input pad, and a third output pad floated, the output pad part being cut along a film cutting line.

### CROSS-REFERENCE TO RELATED APPLICATIONS

This application claims the benefit of the Korean Patent Application No. 10-2024-0002815 filed in the Republic of Korea on Jan. 8, 2024, which is hereby incorporated by reference as if fully set forth herein.

### BACKGROUND

### Technical Field

The present disclosure relates to a chip on film and a display apparatus including the same.

### Description of the Related Art

Display apparatuses include a display panel where a plurality of pixels are provided and a driver integrated circuit (IC) which supplies a driving signal to the pixels.

The driver IC may be mounted on a conductive film and may then be bonded to a display panel by a film on glass (FOG) bonding process. The conductive film with the driver IC mounted thereon may be referred to as a chip on film (COF). The FOG bonding process is a process which applies heat and pressure to the chip on film COF for a certain time by using a conductive ball to bond the chip on film COF to the display panel. The conductive ball is compressed between the chip on film COF and a substrate by heat and pressure, and thus, an output pad of the chip on film COF is electrically connected to a signal pad of the display panel.

As a resolution of a display panel increases, the number of output pads of the chip on film COF increases. When a number of output pads are in a predetermined area, an align operation of a bonding process is difficult. Misalignment may cause a bonding defect.

### BRIEF SUMMARY

To overcome the aforementioned limitation of the related art, the present disclosure may provide a chip on film and a display apparatus including the same, which may reduce or prevent the occurrence of a bonding defect even when a precise align operation is difficult.

Moreover, the present disclosure may provide a chip on film and a display apparatus including the same, in which the number of output pads exposed through a cross-sectional surface of an output pad part may be reduced, thereby reducing or minimizing a defect caused by metal migration.

Moreover, the present disclosure may provide a chip on film and a display apparatus including the same, in which the uniformity of a bonding adhesive force corresponding to an output pad part may increase.

To achieve these benefits and other advantages and in accordance with the purpose of the disclosure, as embodied and broadly described herein, a chip on film includes: a driver integrated circuit; an input pad part including a first input pad connected to the driver integrated circuit and a second input pad separated from the driver integrated circuit; and an output pad part including a first output pad connected to the driver integrated circuit, a second output pad directly connected to the second input pad, and a third output pad floated, the output pad part being cut along a film cutting line.

In another aspect of the present disclosure, a display apparatus includes: a display panel including a display area where pixels are disposed and a bezel region outside the display area; and a chip on film bonded to the bezel region, wherein the chip on film includes: a driver integrated circuit; an input pad part including a first input pad connected to the driver integrated circuit and a second input pad separated from the driver integrated circuit; and an output pad part including a first output pad connected to the driver integrated circuit, a second output pad directly connected to the second input pad, and a third output pad floated, and the output pad part is cut along a film cutting line.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram illustrating a display apparatus according to the present embodiment;

FIG. 2 is a diagram illustrating an example where a printed circuit board is electrically connected to a display panel through a chip on film according to the present embodiment;

FIG. 3 is a diagram illustrating an example where an output pad part of a chip on film is connected to a test pad part;

FIG. 4 is a diagram illustrating an output pad part of a chip on film which is cut along a film cutting line;

FIG. 5 is a diagram illustrating a portion of a cross-sectional surface of an output pad part corresponding to a film cutting line; and

FIG. 6 is a diagram illustrating elements for increasing the uniformity of a bonding adhesive force corresponding to an output pad part.

### DETAILED DESCRIPTION

Hereinafter, the present disclosure will be described more fully with reference to the accompanying drawings, in which exemplary embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the claims are not limited by the disclosure.

The shapes, sizes, ratios, angles, numbers and the like disclosed in the drawings for description of various embodiments of the present disclosure to describe embodiments of the present disclosure are merely exemplary and the present disclosure is not limited thereto. Like reference numerals refer to like elements throughout. Throughout this specification, the same elements are denoted by the same reference numerals. As used herein, the terms “comprise,” “having,” “including” and the like suggest that other parts can be added unless the term “only” is used. As used herein, the singular forms “a,” “an,” and “the” are intended to include the plural forms as well, unless context clearly indicates otherwise.

Elements in various embodiments of the present disclosure are to be interpreted as including margins of error even without explicit statements.

In describing a position relationship, for example, when a position relation between two parts is described as “on˜,” “over˜,” “under˜,” and “next˜,” one or more other parts may be disposed between the two parts unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

In the following description, when the detailed description of the relevant known function or configuration is determined to unnecessarily obscure the important point of the present disclosure, the detailed description will be omitted or may be briefly provided. Hereinafter, embodiments of the present disclosure will be described in detail with reference to the accompanying drawings.

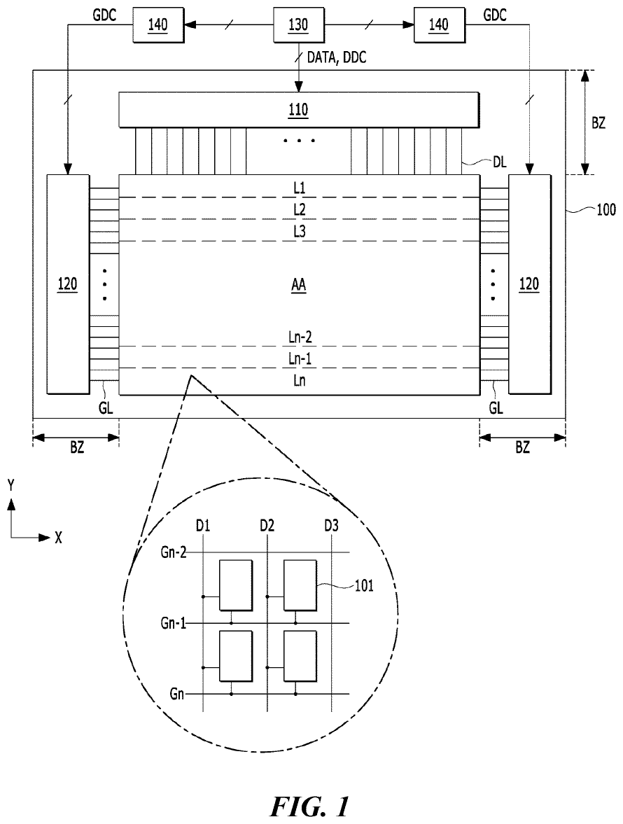

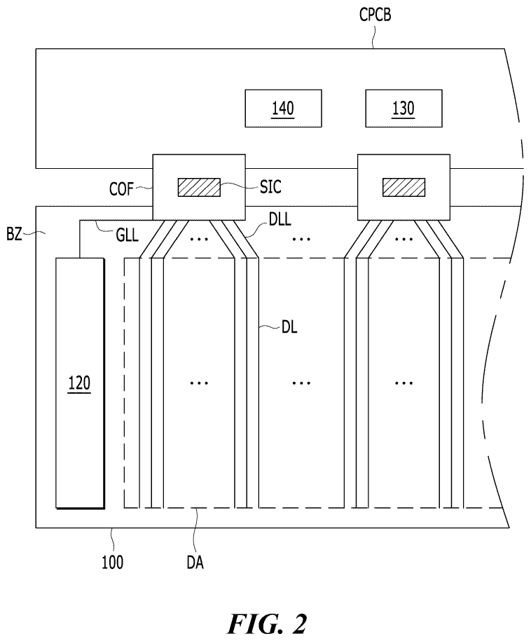

FIG. 1 is a block diagram illustrating a display apparatus according to the present embodiment. FIG. 2 is a diagram illustrating an example where a printed circuit board (PCB) is electrically connected to a display panel through a chip on film COF according to the present embodiment.

Referring to FIGS. 1 and 2, the display apparatus according to the present embodiment may be implemented as a flat display apparatus such as a liquid crystal display (LCD) apparatus, an electroluminescent display apparatus, an electrophoretic display apparatus, an electro-wetting display apparatus, an organic light emitting display apparatus, or a quantum dot display apparatus. Furthermore, the display apparatus according to the present embodiment is not limited to the flat display apparatus and may be implemented as various types such as a curved display apparatus, a foldable display apparatus, a rollable display apparatus, and a transparent display apparatus.

In the following embodiments, the display apparatus may be described as a flat LCD apparatus, but the inventive concept is not limited thereto.

The display panel 100 may be implemented with a glass substrate or a plastic substrate. A plurality of data lines DL, a plurality of gate lines GL intersecting with the data lines DL, and a pixel electrode may be formed in a substrate of the display panel 100.

Pixels 101 may be arranged as a matrix type in the display panel 100, based on an intersection structure between the data lines DL and the gate lines GL. Each of the pixels 101 may include a thin film transistor (TFT), a pixel electrode connected to the TFT, and a storage capacitor.

In the display panel 100, the pixels 101 may configure a screen AA which displays an input image. The screen AA may include a pixel array which displays pixel data of the input image (hereinafter referred to as image data) DATA. The pixel array may include the plurality of data lines DL, the plurality of gate lines GL intersecting with the data lines DL, and a plurality of pixels. The pixels may be arranged as various types, such as a matrix type, a stripe type, or a diamond type, on the screen AA. Each of the pixels may include a red (R) pixel 101, a green (G) pixel 101, and a blue (B) pixel 101 so as to implement colors, and moreover, may further include a white (W) pixel.

The pixel array may include a plurality of pixel columns and a plurality of pixel lines L1 to Ln intersecting with the pixel columns. One pixel column may include pixels 101 which are arranged in a Y-axis direction. One pixel line may include pixels 101 which are arranged in an X-axis direction. One vertical period may be one frame period needed for writing image data DATA of one frame in all pixels 101 of the screen AA. One horizontal period may be a time obtained by dividing one frame period by the number of pixel lines L1 to Ln. One horizontal period may be a time needed for writing the image data DATA of one pixel line, sharing a gate line GL, in pixels of one pixel line. In FIG. 1, “D1 to D3” illustrated in a circle may be data lines, and “Gn−2 to Gn” may be gate lines.

In the display panel 100, when a region where the screen AA is disposed is referred to as a display area DA, an outer region of the display area DA may be referred to as a bezel region BZ. The bezel region BZ may be a region which is covered by an external case and may not display an image.

A display panel driver may include a source driver 110 and a gate driver 120. The display panel driver may write image data DATA in the pixels 101 of the display panel 100, based on control by the timing controller 130.

The source driver 110 may include a digital-to-analog converter (DAC). The DAC may receive the image data DATA and a source timing control signal DDC from the timing controller 130. The DAC may convert the image data DATA into a gamma compensation voltage to generate data voltages, based on the source timing control signal DDC, and may supply the data voltages to the data lines DL during one horizontal period. The data voltages may be supplied to the data lines DL and may then be applied to target electrodes of the pixels 101 through TFTs. In LCD apparatus, the target electrode may be a pixel electrode, and in electroluminescent display apparatuses, the target electrode may be a gate electrode of a driving element.

The source driver 110 may be disposed outside the screen AA in the display panel 100 and may be disposed in the bezel region BZ which does not display an image. The source driver 110 may include one or more driver integrated circuits SIC.

The driver integrated circuit SIC may be mounted on a conductive film and may then be bonded to the bezel region BZ of the display panel 100 by a film on glass (FOG) bonding process. The conductive film with the driver integrated circuit SIC mounted thereon may be referred to as a chip on film COF. The FOG bonding process is a process which applies heat and pressure to the chip on film COF for a certain time by using a conductive ball to bond the chip on film COF to the display panel 100. The conductive ball is compressed between the chip on film COF and a substrate by heat and pressure, and thus, an output pad of the chip on film COF is electrically connected to a signal pad of the display panel 100.

The signal pad of the display panel 100 may include first panel pads connected to data link lines DLL and a second panel pad connected to a gate link line GLL. The data link lines DLL and the gate link line GLL may be disposed in the bezel region BZ. The data link lines DLL may be individually connected to the data lines DL. The gate link line GLL may be connected to the gate driver 120.

An input pad of the chip on film COF may be connected to signal lines of a printed circuit board CPCB through a bonding process. The timing controller 130 and the level shifter 140 may be mounted on the printed circuit board CPCB. The timing controller 130 may be connected to the level shifter 140 through the signal lines, and moreover, may be connected to the input pad of the chip on film COF.

The gate driver 120 may sequentially supply a gate signal, synchronized with a data voltage, to the gate lines GL according to control by the timing controller 130. The gate driver 120 may output the gate signal, based on a gate timing control signal GDC transferred through the gate link line GLL. The gate signal may simultaneously activate pixels 101 of a pixel line charged with the data voltage during at least one horizontal period. The gate driver 120 may include one or more gate shift registers. The gate shift register may output the gate signal while shifting the gate signal in a line progressive/non-progressive scheme, based on a gate timing control signal GDC. The gate signal may include one or more scan signals.

The gate driver 120 may be disposed outside the screen AA in the display panel 100 and may be formed in the bezel region BZ which does not display an image.

The timing controller 130 may receive video data DATA and a timing signal, synchronized with the video data DATA, from a host system. The timing signal may include a vertical synchronization signal Vsync, a horizontal synchronization signal Hsync, a clock signal DCLK, and a data enable signal DE. The vertical synchronization signal Vsync may define a vertical period. The horizontal synchronization signal Hsync may define a horizontal period. The data enable signal DE may define a time where the video data DATA is transferred in a vertical period or a horizontal period. The vertical period and the horizontal period may be detected by a method of counting the data enable signal DE, and thus, the vertical synchronization signal Vsync and the horizontal synchronization signal Hsync may be omitted.

The timing controller 130 may generate the source timing control signal DDC for controlling an operation timing of the source driver 110 and the gate timing control signal GDC for controlling an operation timing of the gate driver 120, based on the timing signals Vsync, Hsync, and DE received from the host system. The source timing control signal DDC may include a source sampling clock for sampling image data DATA and a source output enable signal for setting an output timing of a data voltage.

The host system may be one of a television (TV), a set-top box, a navigation system, a personal computer (PC), a home theater, an automotive display system, a mobile device, and a wearable device. In the mobile device and the wearable device, the source driver 110, the timing controller 130, and the level shifter 140 may be integrated into one driver integrated circuit.

The level shifter 140 may shift a logic voltage of the gate timing control signal GDC having a first amplitude, input from the timing controller 130, to a gate high voltage VGH or a gate low voltage VGL, having a second amplitude which is greater than the first amplitude, to supply to the gate driver 120 through the chip on film COF and the gate link line GLL. In the level shifter 140, a low logic voltage of the gate timing control signal GDC may be shifted to the gate low voltage VGL, and a high logic voltage of the gate timing control signal GDC may be shifted to the gate high voltage VGH.

The timing controller 130 may transfer the image data DATA and the source timing control signal DDC to the driver integrated circuit SIC through an internal interface circuit. The internal interface circuit may be implemented as an embedded clock point to point interface (EPI), but is not limited thereto.

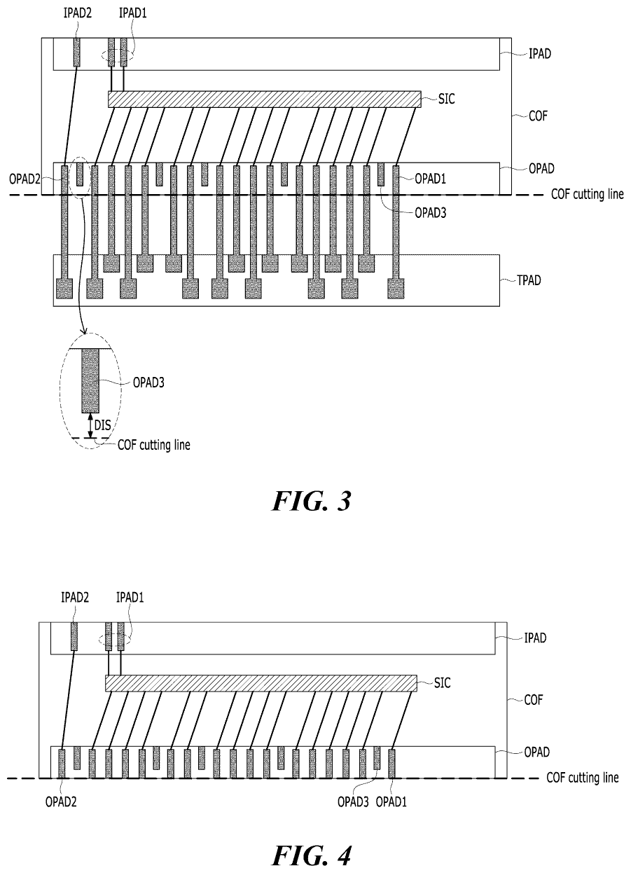

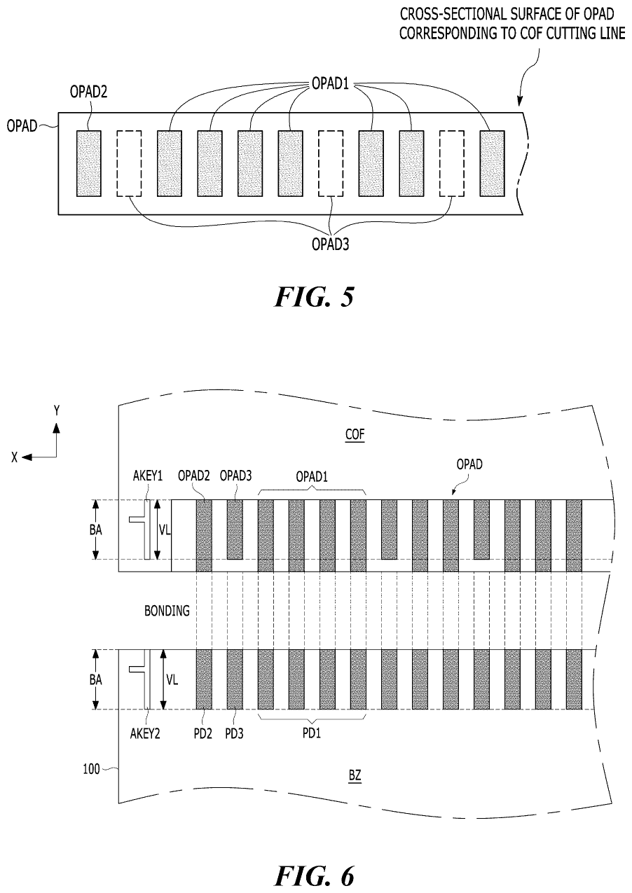

FIG. 3 is a diagram illustrating an example where an output pad part of a chip on film is connected to a test pad part. FIG. 4 is a diagram illustrating an output pad part of a chip on film which is cut along a film cutting line. FIG. 5 is a diagram illustrating a portion of a cross-sectional surface of an output pad part corresponding to a film cutting line.

Referring to FIG. 3, a chip on film COF according to the present embodiment may include a driver integrated circuit SIC, an input pad part IPAD bonded to a printed circuit board, and an output pad part OPAD bonded to a display panel.

The input pad part IPAD may include a first input pad IPAD1 which is connected to the driver integrated circuit SIC and a second input pad IPAD2 which is not connected to the driver integrated circuit SIC. The first input pad IPAD1 may receive an EPI signal from a timing controller to transfer to the driver integrated circuit SIC. The second input pad IPAD2 may receive a gate timing control signal from a level shifter to supply to the second input pad IPAD2.

The output pad part OPAD may include a first output pad OPAD1 which is connected to the driver integrated circuit SIC through a COF connection line, a second output pad OPAD2 which is directly connected to the second input pad IPAD2 through the COF connection line, and a third output pad OPAD3 which is floated without being connected to the COF connection line.

The third output pad OPAD3 may be disposed between the first output pad OPAD1 and the second output pad OPAD2 or between adjacent first output pads OPAD1 and may be in a floating state, thereby increasing a bonding margin. That is, even without a precise align operation between the chip on film COF and the display panel 100, a bonding defect between the output pad part OPAD and the display panel 100 may be effectively reduced or prevented by the third output pad OPAD3 having a floating state.

To secure a bonding margin, one or more first output pads may be disposed between adjacent third output pads OPAD3.

Referring to FIG. 3, the chip on film COF according to the present embodiment may undergo a test process prior to a bonding process of bonding the printed circuit board to the display panel. The test process may be a process of testing whether the COF connection line and the driver integrated circuit SIC included in the chip on film COF are normal or not.

For the test process, a test pad part TPAD may be connected to the output pad part OPAD of the chip on film COF. Test pads included in the test pad part TPAD may be connected to first and second output pads OPAD1 and OPAD2 of the output pad part OPAD and may not be connected to a third output pad OPAD3. This may be because the third output pad OPAD3 has a floating state without being connected to the COF connection line, and thus, it is not needed to test whether a connection is normal or not.

When the test process is completed, the output pad part OPAD of the chip on film COF may be cut along a film cutting line (i.e., a COF cutting line) as in FIG. 4. At this time, because a lower end portion of the third output pad OPAD3 is spaced apart from the film cutting line by a certain interval DIS and is disposed inward from a film, the first and second output pads OPAD1 and OPAD2 may be exposed at the outside in a cross-sectional surface of the output pad part OPAD corresponding to the film cutting line, and the third output pad OPAD3 may not be exposed at the outside.

That is, as in FIG. 5, because the third output pad OPAD3 is not exposed at the outside in a cross-sectional surface of the output pad part OPAD corresponding to the film cutting line, the number of output pads exposed through the cross-sectional surface of the output pad part OPAD may decrease. As a result, a short circuit defect caused by metal migration occurring in the cross-sectional surface of the output pad part OPAD may be reduced or minimized.

FIG. 6 is a diagram illustrating elements for increasing the uniformity of a bonding adhesive force corresponding to an output pad part.

Referring to FIG. 6, the output pad part OPAD of the chip on film COF cut along the film cutting line may be bonded to a signal pad part of the bezel region BZ of the display panel 100 through an FOG bonding process.

The signal pad part may include a plurality of first panel pads PD1 bonded to a plurality of first output pads OPAD1, a second panel pad PD2 bonded to the second output pad OPAD2, and a plurality of third panel pads PD3 bonded to a plurality of third output pads OPAD3.

The plurality of first panel pads PD1 may be connected to the data link lines (DLL of FIG. 2). Data voltages output from the plurality of first output pads OPAD1 may be supplied to the data link lines (DLL of FIG. 2) via the plurality of first panel pads PD1.

The second panel pad PD2 may be connected to the gate link lines (GLL of FIG. 2). The gate timing control signal output from the second output pad OPAD2 may be supplied to the gate link line (GLL of FIG. 2) via the second panel pad PD2.

The plurality of third panel pads PD3 may be floated dummy pads. The plurality of third panel pads PD3 may be used for bonding to the plurality of third output pads OPAD3, and moreover, may not be connected to the other signal lines.

The reason that the third output pad OPAD3 is additionally bonded to the third panel pad PD3 may be for increasing the stability of an FOG bonding process which are simultaneously performed on the output pad part OPAD and the signal pad part. Unless the stability of an FOG bonding process is reduced, the third panel pad PD3 used for only bonding may be omitted.

For a bonding process between the output pad part OPAD and the display panel 100, a first align key AKEY1 may be included in the chip on film COF, and a second align key AKEY2 may be included in the display panel 100. The first align key AKEY1 may be the same as or similar to the second align key AKEY2.

In the chip on film COF, the first align key AKEY1 may be disposed near the output pad part OPAD in a horizontal (X axis) direction. In the display panel 100, the second align key AKEY2 may be disposed near the signal pad part in the horizontal (X axis) direction.

In the output pad part OPAD, the bonding region BA may be defined with respect to the first align key AKEY1. Likewise, in the display panel 100, the bonding region BA may be defined with respect to the second align key AKEY2.

A vertical (Y axis) length VL of the bonding region BA may be the same as or similar to a vertical (Y axis) length VL of the first align key AKEY1 or the second align key AKEY2.

According to the present embodiment, in order to increase the uniformity of a bonding adhesive force corresponding to the output pad part OPAD, a vertical (Y axis) length VL of the third output pad OPAD3 may be the same as or similar to the vertical (Y axis) length VL of the first align key AKEY1. Accordingly, bonding of the same or substantially same area corresponding to the same or substantially same vertical (Y axis) length VL may be performed on all output pads OPAD1, OPAD2, and OPAD3 included in the output pad part OPAD, and thus, the uniformity of a bonding adhesive force corresponding to the output pad part OPAD may be enhanced.

The present embodiment may realize the following effects.

The present embodiment may reduce or prevent the occurrence of a bonding defect even when a precise align operation is difficult.

Moreover, the present embodiment may decrease the number of output pads exposed through a cross-sectional surface of an output pad part, thereby reducing or minimizing a defect caused by metal migration.

Moreover, the present embodiment may increase the uniformity of a bonding adhesive force corresponding to an output pad part.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the technical idea and scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A chip on film comprising:
a substrate;
a driver integrated circuit on the substrate;
a plurality of input pads including a first input pad connected to the driver integrated circuit and a second input pad separated from the driver integrated circuit; and
a plurality of output pads including a first output pad connected to the driver integrated circuit, a second output pad directly connected to the second input pad, and a third output pad spaced from a film cutting line, the plurality of output pads configured to be cut along the film cutting line.

2. The chip on film of claim 1, wherein the first and second output pads are exposed at a cross-sectional surface of the substrate corresponding to the film cutting line, and the third output pad is spaced from the cross-sectional surface.

3. The chip on film of claim 1, wherein the third output pad is disposed between the first output pad and the second output pad or between successive first output pads of the plurality of output pads.

4. The chip on film of claim 1, wherein an end portion of the third output pad is disposed inward from an edge of the substrate.

5. The chip on film of claim 1, wherein one or more first output pads are disposed between successive third output pads.

6. The chip on film of claim 1, further comprising an align key disposed proximate the plurality of output pads in a horizontal direction and configured to assist in a bonding process between the output pad part and a display panel,
wherein a bonding region corresponding to the plurality of output pads is defined with respect to the align key, and
a vertical length of the bonding region is equal to a vertical length of the align key.

7. The chip on film of claim 6, wherein a vertical length of the third output pad is equal to the vertical length of the align key.

8. A display apparatus comprising:
a display panel including a display area and a bezel region outside of the display area; and
a chip on film bonded to the bezel region, wherein the chip on film includes:
a driver integrated circuit;
a plurality of input pads including a first input pad connected to the driver integrated circuit and a second input pad separated from the driver integrated circuit; and
a plurality of output pads including a first output pad connected to the driver integrated circuit, a second output pad directly connected to the second input pad, and a third output pad spaced from a film cutting line,
wherein the plurality of output pads are configured to be cut along the film cutting line.

9. The display apparatus of claim 8, wherein the first and second output pads are exposed at a cross-sectional surface of the chip on film corresponding to the film cutting line, and the third output pad is spaced from the cross-sectional surface.

10. The display apparatus of claim 8, wherein the third output pad is disposed between the first output pad and the second output pad or between successive first output pads of the plurality of output pads.

11. The display apparatus of claim 8, wherein an end portion of the third output pad is disposed inward from an edge of a film of the chip on film.

12. The display apparatus of claim 8, wherein one or more first output pads are disposed between successive third output pads.

13. The display apparatus of claim 8, further comprising an align key disposed proximate the plurality of output pads in a horizontal direction and configured to assist in a bonding process between the output pad part and the display panel,
wherein a bonding region corresponding to the plurality of output pads is defined with respect to the align key, and
a vertical length of the bonding region is equal to a vertical length of the align key.

14. The display apparatus of claim 13, wherein a vertical length of the third output pad is equal to the vertical length of the align key.

15. A chip on film comprising:
a substrate;
a driver integrated circuit on the substrate;
a plurality of input pads; and
a plurality of output pads including first output pads and at least one second output pad, wherein the at least one second output pad is spaced from a film cutting line along which the plurality of output pads are configured to be cut.

16. The chip on film of claim 15, wherein only the first output pads are exposed at an edge of the substrate corresponding to the film cutting line.

17. The chip on film of claim 16, wherein an end of the at least one second output pad is spaced from the edge of the substrate.

18. The chip on film of claim 15, wherein one or more first output pads are disposed between successive second output pads.

19. The chip on film of claim 15, further comprising an align key disposed proximate the plurality of output pads in a horizontal direction,
wherein the align key defines a bonding region corresponding to the plurality of output pads, and
a vertical length of the bonding region is equal to a vertical length of the align key.

20. The chip on film of claim 19, wherein a vertical length of the at least one second output pad is equal to the vertical length of the align key.
